(19) United States
(12) Patent Application Publication
(10) Pub. No.: US 2024/0243038 A1
(43) Pub. Date: Jul. 18, 2024

(54) INTEGRATED CIRCUIT INCLUDING BACK-SIDE WIRING AND A METHOD OF DESIGNING THE SAME

(71) Applicant: SAMSUNG ELECTRONICS CO., LTD., SUWON-SI (KR)

(72) Inventors: Eojin LEE, Suwon-si (KR); Taehyung KIM, Suwon-si (KR); Hoyoung TANG, Suwon-si (KR); Jaehyun LIM, Suwon-si (KR)

(21) Appl. No.: 18/515,384

(22) Filed: Nov. 21, 2023

(30) Foreign Application Priority Data
Jan. 16, 2023 (KR) 10-2023-0006324
Apr. 11, 2023 (KR) 10-2023-0047581

(51) Int. Cl. H01L 23/48; H01L 29/06; H01L 29/417; H01L 29/423; H01L 29/78; H10B 10/00

(52) U.S. Cl. CPC H01L 23/481; H01L 29/0673; H01L 29/41733; H01L 29/41791; H01L 29/42392; H01L 29/7851; H10B 10/125

(57) ABSTRACT

An integrated circuit includes: a substrate including a cell area and a dummy area, wherein a plurality of cells are arranged in the cell area; a front-side wiring layer arranged over a front surface of the substrate in a vertical direction, wherein the front-side wiring layer includes a first pattern extending in a first direction across the cell area and the dummy area and a second pattern extending in a second direction intersecting the first direction and contacting the first pattern; a through via overlapping the front-side wiring layer in the vertical direction in the dummy area and passing through the substrate; and a back-side wiring layer arranged on a rear surface of the substrate, wherein the back-side wiring layer is connected through the through via and the front-side wiring layer to at least one transistor included in the plurality of cells.

### CROSS-REFERENCE TO RELATED APPLICATIONS

This application claims priority under 35 U.S.C. § 119 to Korean Patent Application No. 10-2023-0006324, filed on Jan. 16, 2023, and Korean Patent Application No. 10-2023-0047581, filed on Apr. 11, 2023, in the Korean Intellectual Property Office, the disclosures of which are incorporated by reference herein in their entireties.

### TECHNICAL FIELD

The inventive concept relates to an integrated circuit, and more particularly, to an integrated circuit including back-side wiring and a method of designing the integrated circuit.

### DISCUSSION OF RELATED ART

As semiconductor technologies evolve to meet demands for higher integration, the dimensions of wires of integrated circuits such as width, interval, and/or height tend to decrease. This reduction can amplify the influence of parasitic components in the wiring. Additionally, as power supply voltages in integrated circuits decrease for reduced power consumption and faster operation speeds, the influence of parasitic components may further increase. Despite these parasitic components, an integrated circuit including cell arrays of uniform structure should maintain stable and high performance operation to meet the needs of various applications.

### SUMMARY

The inventive concept provides an integrated circuit that can stably transmit a voltage applied to back-side wiring to a cell array and a method of designing the integrated circuit.

According to an embodiment of the inventive concept, there is provided an integrated circuit including: a substrate including a cell area and a dummy area, wherein a plurality of cells are arranged in the cell area; a front-side wiring layer arranged over a front surface of the substrate in a vertical direction, wherein the front-side wiring layer includes a first pattern extending in a first direction across the cell area and the dummy area and a second pattern extending in a second direction intersecting the first direction and contacting the first pattern; a through via overlapping the front-side wiring layer in the vertical direction in the dummy area and passing through the substrate; and a back-side wiring layer arranged on a rear surface of the substrate, wherein the back-side wiring layer is connected through the through via and the front-side wiring layer to at least one transistor included in the plurality of cells.

According to an embodiment of the inventive concept, there is provided an integrated circuit including: a substrate including a cell area and a dummy area, wherein the cell area includes a plurality of cells; a front-side wiring layer arranged over the cell area and the dummy area in a vertical direction, wherein the front-side wiring layer has a mesh shape; a back-side wiring layer arranged on a rear surface of the substrate; and a plurality of through vias overlapping the front-side wiring layer in the vertical direction in the dummy area and passing through the substrate, wherein a voltage applied to the back-side wiring layer passes through the plurality of through vias and the front-side wiring layer to at least one transistor included in the plurality of cells.

According to an embodiment of the inventive concept, there is provided an integrated circuit including: a substrate including a cell area and a dummy area adjacent to the cell area, wherein the cell area includes a plurality of cells: a first wiring layer arranged over a front surface of the substrate in a vertical direction; a second wiring layer arranged over the first wiring layer in the vertical direction and having a mesh shape across the cell area and the dummy area; a back-side wiring layer which is arranged on a rear surface of the substrate and to which a first supply voltage is applied; a through via overlapping the second wiring layer in the vertical direction in the dummy area and connected to the back-side wiring layer by passing through the substrate, and a via extending in the vertical direction in the dummy area and connecting the through via to the first wiring layer, wherein the first supply voltage is applied through the back-side wiring layer to pass through the through via, the via, the first wiring layer, and the second wiring layer to a source/drain area of at least one transistor included in the plurality of cells.

### BRIEF DESCRIPTION OF THE DRAWINGS

Embodiments of the inventive concept will be more clearly understood from the following detailed description taken in conjunction with the accompanying drawings in which:

FIG. 1 illustrates a layout of an integrated circuit according to an embodiment;

FIG. 2 illustrates a cell arranged in a cell area of FIG. 1 according to an embodiment;

FIGS. 3A, 3B, 3C and 3D respectively illustrate elements according to some embodiments;

FIG. 4 is a block diagram illustrating a memory device included in an integrated circuit according to an embodiment;

FIG. 5 is a plan view illustrating a layout of an integrated circuit according to an embodiment;

FIG. 6 is a circuit diagram illustrating a cell array according to an embodiment;

FIG. 7 illustrates a layout of an integrated circuit according to an embodiment;

FIG. 8 is a cross-sectional view taken along line X1-X1′ of FIG. 7 according to an embodiment;

FIG. 9 is a cross-sectional view taken along line X1-X1′ of FIG. 7 according to an embodiment;

FIG. 10 illustrates a layout of an integrated circuit according to an embodiment;

FIG. 11 illustrates a layout of an integrated circuit according to an embodiment;

FIG. 12 illustrates a layout of an integrated circuit according to an embodiment;

FIG. 13 illustrates a layout of an integrated circuit according to an embodiment;

FIG. 14 is a cross-sectional view taken along line Y1-Y1′ of FIG. 13 according to an embodiment;

FIG. 15 is a cross-sectional view taken along line Y1-Y1′ of FIG. 13 according to an embodiment;

FIG. 16 illustrates a layout of an integrated circuit according to an embodiment,

FIG. 17 illustrates a layout of an integrated circuit according to an embodiment;

FIG. 18 illustrates a layout of an integrated circuit according to an embodiment;

FIG. 19 is a flowchart illustrating a method of manufacturing an integrated circuit, according to an embodiment;

FIG. 20 is a flowchart illustrating a method of designing an integrated circuit, according to an embodiment;

FIG. 21 is a block diagram illustrating a system-on-chip (SoC) according to an embodiment; and

FIG. 22 is a block diagram illustrating a computing system including a memory storing a program, according to an embodiment.

### DETAILED DESCRIPTION OF THE EMBODIMENTS

Hereinafter, embodiments of the inventive concept will be described in detail with reference to the accompanying drawings.

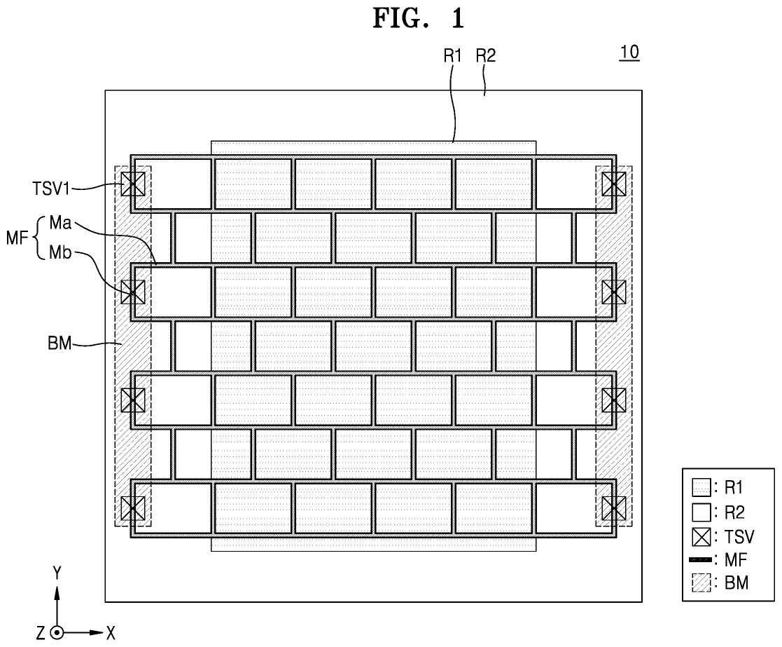

FIG. 1 illustrates a layout of an integrated circuit 10 according to an embodiment.

Referring to FIG. 1, the integrated circuit 10 may include a first area R1 and a second area R2, and the second area R2 may surround the first area R1. For example, the first area R1 may correspond to a “cell area” in which a plurality of memory cells are arranged. Herein, the memory cells may be referred to as bit cells or cells. For example, the second area R2 may correspond to a “dummy area” in which a plurality of dummy cells are arranged. Hereinafter, the first area R1 is referred to as a cell area R1 and the second area R2 is referred to as a dummy area R2.

The integrated circuit 10 may further include a front-side wiring layer MF arranged over the cell area R1 and the dummy area R2 in the vertical direction Z. The front-side wiring layer MF may include a plurality of patterns or a plurality of conductive patterns including a conductive material. Herein, a “pattern” may refer to a conductive pattern. The front-side wiring layer MF may include first patterns Ma extending in the first direction X and second patterns Mb extending in the second direction Y. In this case, the first direction X and the second direction Y may be perpendicular to each other. The first patterns Ma may be arranged in the second direction Y and the second patterns Mb may be arranged in the first direction X.

Each of the first patterns Ma may extend across the cell area R1 and the dummy area R2. As such, the first pattern Ma extending in one direction may be referred to as a “line”. Accordingly, the first patterns Ma may also be referred to as first lines or first conductive lines. The second patterns Mb may include patterns arranged over the cell area R1 and patterns arranged over the dummy area R2. Additionally, the second patterns Mb may further include patterns arranged over the boundary between the cell area R1 and the dummy area R2. For example, the second patterns Mb may be respectively connected between two first patterns Ma spaced apart from each other in the second direction Y.

In an embodiment, the front-side wiring layer MF may be arranged in a mesh shape. For example, each of the first patterns Ma may contact some of the second patterns Mb. For example, one of the first patterns Ma may contact one of the second patterns Mb to form a corner. However, the inventive concept is not limited thereto, and the front-side wiring layer MF may be implemented in various shapes arranged across the cell area R1 and the dummy area R2.

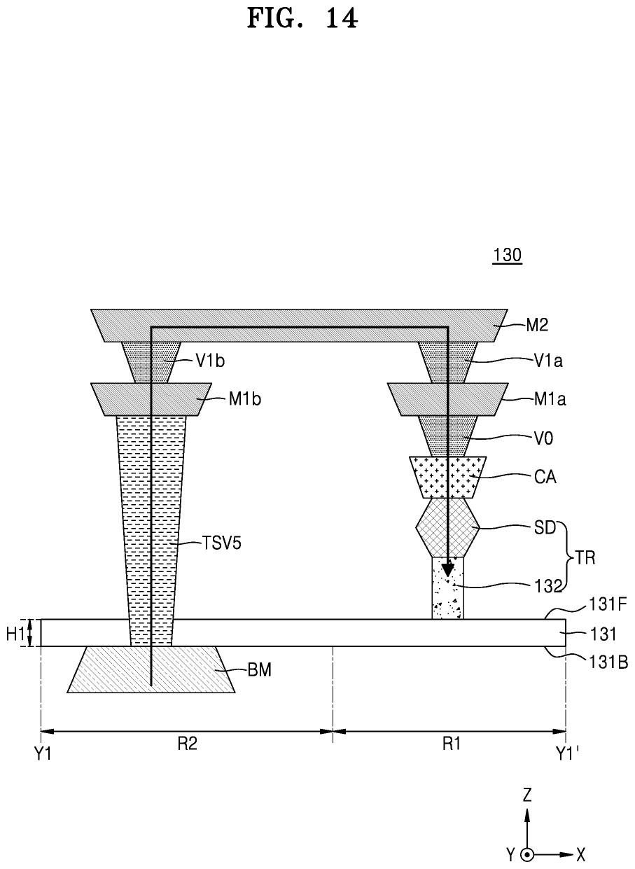

According to embodiments, at least one wiring layer may be further arranged between the cell area R1 and the dummy area R2, and the front-side wiring layer MF. According to embodiments, at least one wiring layer may be further arranged over the front-side wiring layer MF. For example, the front-side wiring layer MF may correspond to a second wiring layer (e.g., M2 of FIG. 14). However, the inventive concept is not limited thereto, and the front-side wiring layer MF may correspond to a first wiring layer under the second wiring layer.

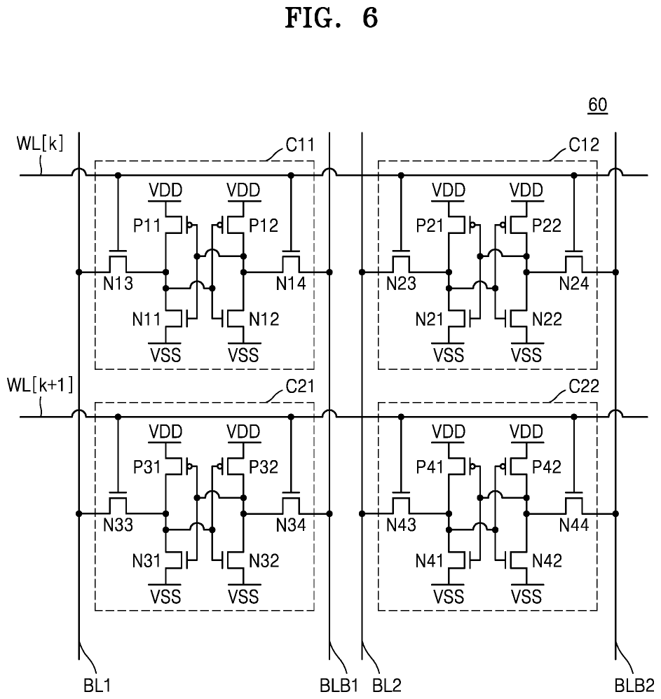

The integrated circuit 10 may further include a back-side wiring layer BM arranged under the cell area R1 and the dummy area R2 in the vertical direction Z. In an embodiment, a negative supply voltage, for example, a first supply voltage corresponding to a ground voltage VSS (see FIG. 6), may be applied to the back-side wiring layer BM. However, the inventive concept is not limited thereto, and in some embodiments, a positive supply voltage, for example, a second supply voltage corresponding to a power supply voltage VDD (see FIG. 6), may be applied to the back-side wiring layer BM. As such, because the integrated circuit 10 includes the back-side wiring layer BM, the routing flexibility of front-side wiring layers arranged over the cell area R1 and the dummy area R2 may be improved.

FIG. 1 illustrates that the back-side wiring layer BM extends in the second direction Y; however, the inventive concept is not limited thereto, and the back-side wiring layer BM may include a plurality of patterns spaced apart from each other in the second direction Y. In other words, the back-side wiring layer BM may not be continuous. In some embodiments, the back-side wiring layer BM may include a plurality of patterns extending in the first direction X or spaced apart from each other in the first direction X. In some embodiments, the back-side wiring layer BM may be arranged in a mesh shape. In some embodiments, the back-side wiring layer BM may include wiring patterns to which a first supply voltage is applied and wiring patterns to which a second supply voltage is applied. As such, the arrangement and/or extension direction of the back-side wiring layer BM may be variously modified according to embodiments.

The integrated circuit 10 may further include a plurality of through silicon vias or through vias TSV arranged in the dummy area R2. For example, the plurality of through vias TSV may include through silicon vias or through vias TSV1 respectively overlapping some second patterns Mb arranged in the dummy area R2, in the vertical direction Z. For example, the through vias TSV1 may be arranged in a line in the second direction Y; however, the inventive concept is not limited thereto. Each of the through vias TSV1 may extend in the vertical direction Z and electrically connect the back-side wiring layer BM to the front-side wiring layer MF. The number and arrangement of through vias TSV1 may be variously modified according to embodiments. Herein, the through via TSV may be connected to the back-side wiring layer BM by passing through a silicon substrate. Thus, the back-side wiring layer BM is connected to a lower surface of the through via TSV.

In the related art, tab cells are arranged in a dummy area of an integrated circuit, and accordingly, power lines connected to the tab cells are further arranged over the dummy area. However, in the integrated circuit 10 according to embodiments, by removing the tab cells and the power lines, the front-side wiring layer MF over the cell area R1 may extend to the dummy area R2 and overlap the back-side wiring layer BM. Accordingly, the back-side wiring layer BM and the front-side wiring layer MF may be directly connected to each other through the through vias TSV1 arranged in the dummy area R2. This configuration significantly reduces the path for transmitting the supply voltage from the back-side wiring layer BM to each cell of the cell area R1. Thus, according to embodiments, because the supply voltage applied to the back-side wiring layer BM is directly transmitted to each cell of the cell area R1 without bypass, an IR drop may be reduced compared to the related art, and thus, the performance and reliability of the integrated circuit 10 may be improved.

Hereinafter, an embodiment in which the front-side wiring layer MF is arranged in a mesh shape is mainly described. However, in some embodiments, the front-side wiring layer MF may include only first lines or first patterns Ma extending in the first direction X across the cell area R1 and the dummy area R2, and the through vias TSV1 may respectively overlap the first patterns Ma. In this case, the supply voltage applied to the back-side wiring layer BM may be transmitted to the cell area R1 through the through vias TSV and the first patterns Ma.

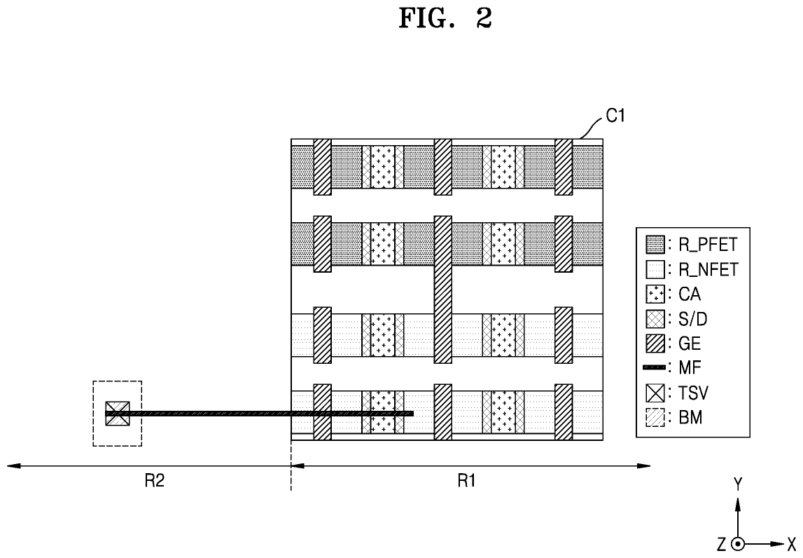

FIG. 2 illustrates a cell C1 arranged in the cell area R1 of FIG. 1 according to an embodiment.

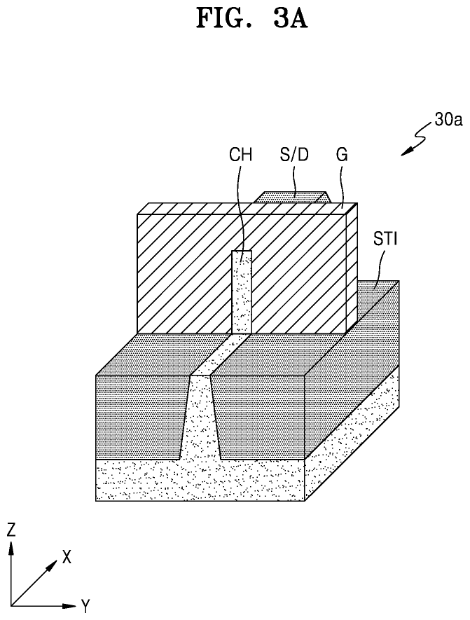

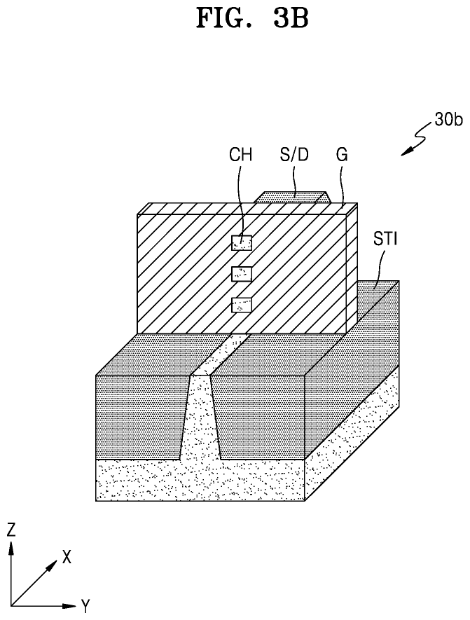

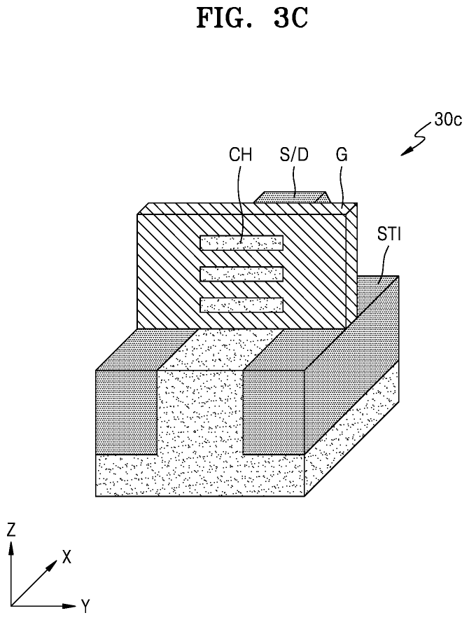

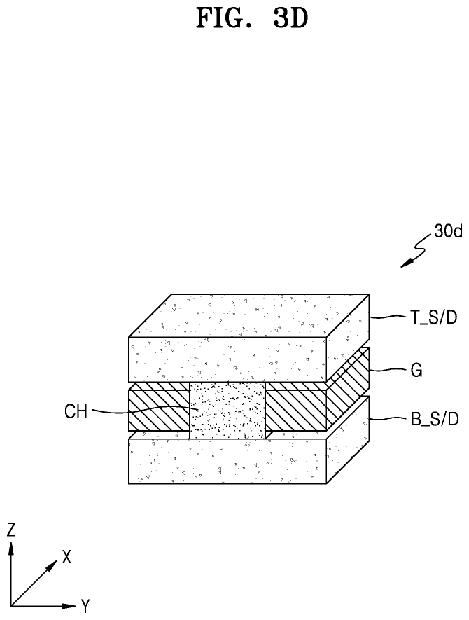

Referring to FIG. 2, the cell C1 may include p-channel field effect transistor (PFET) areas R_PFET and n-channel field effect transistor (NFET) areas R_NFET extending in the first direction X and may further include gate electrodes GE extending in the second direction Y. The gate electrodes GE may intersect the PFET areas R_PFET and the NFET areas R_NFET. As described below with reference to FIGS. 3A to 3C, a gate electrode GE and portions of the PFET areas R_PFET and the NFET areas R_NFET protruding in the vertical direction Z and extending in the second direction Y may form a transistor and the portions may be referred to as an active pattern. Source/drain areas S/D may be formed on both sides of the gate electrode GE, and a contact CA may be formed over each of the source/drain areas S/D. A channel may be formed between the source/drain areas S/D under the gate electrode GE, and examples of the channel are described below with reference to FIGS. 3A to 3D. A transistor may be formed by the gate electrode GE and the source/drain areas S/D. Examples of the transistor as an active element are described below with reference to FIGS. 3A to 3D.

The through via TSV arranged in the dummy area R2 may extend in the vertical direction Z and may electrically connect the back-side wiring layer BM to the front-side wiring layer MF. Accordingly, the supply voltage applied to the back-side wiring layer BM may pass through the through via TSV and the front-side wiring layer MF to the source or drain of the transistor included in the cell C1. For example, a ground voltage may be applied to the back-side wiring layer BM, and the ground voltage may pass through the through via TSV and the front-side wiring layer MF to the source of the transistor formed in the NFET area R_NFET of the cell C1.

FIGS. 3A to 3D respectively illustrate elements according to some embodiments. For example, FIG. 3A illustrates a fin field effect transistor (FinFET) 30a, FIG. 3B illustrates a gate-all-around field effect transistor (GAAFET) 30b, FIG. 3C illustrates a multi-bridge channel field effect transistor (MBCFET) 30c, and FIG. 3D illustrates a vertical field effect transistor (VFET) 30d. For convenience of illustration, FIGS. 3A to 3C illustrate a state in which one of two source/drain areas is removed, and FIG. 3D illustrates a cross-section of the VFET 30d taken along a plane that is parallel to a plane formed in the second direction Y and the vertical direction Z and passes through a channel CH of the VFET 30d.

Referring to FIG. 3A, the FinFET 30a may be formed by a fin-shaped active pattern extending in the first direction X between shallow trench isolations STI and a gate G extending in the second direction Y. Source/drain areas S/D may be formed on both sides of the gate G, and accordingly, the source and the drain may be spaced apart from each other in the first direction X. An insulating layer may be formed between the channel CH and the gate G. In some embodiments, the FinFET 30a may be formed by a gate G and a plurality of active patterns spaced apart from each other in the second direction Y.

Referring to FIG. 3B, the GAAFET 30b may be formed by active patterns (e.g., nanowires) spaced apart from each other in the vertical direction Z and extending in the first direction X and a gate G extending in the second direction Y. Source/drain areas S/D may be formed on both sides of the gate G, and accordingly, the source and the drain may be spaced apart from each other in the first direction X. An insulating layer may be formed between the channel CH and the gate G. In addition, the number of nanowires included in the GAAFET 30b is not limited to that illustrated in FIG. 3B.

Referring to FIG. 3C, the MBCFET 30c may be formed by active patterns (e.g., nanosheets) spaced apart from each other in the vertical direction Z and extending in the first direction X and a gate G extending in the second direction Y. Source/drain areas S/D may be formed on both sides of the gate G, and accordingly, the source and the drain may be spaced apart from each other in the first direction X. An insulating layer may be formed between the channel CH and the gate G. In addition, the number of nanosheets included in the MBCFET 30c is not limited to that illustrated in FIG. 3C.

Referring to FIG. 3D, the VFET 30d may include a top source/drain T_S/D and a bottom source/drain B_S/D spaced apart from each other in the vertical direction Z with a channel CH therebetween. The VFET 30d may include a gate G surrounding the channel CH between the top source/drain T_S/D and the bottom source/drain B_S/D. An insulating layer may be formed between the channel CH and the gate G.

Hereinafter, an integrated circuit including the FinFET 30a or the MBCFET 30c is mainly described; however, elements included in an integrated circuit are not limited to the examples of FIGS. 3A to 3D. For example, an integrated circuit may include a ForkFET that a structure where an N-type transistor and a P-type transistor are positioned more closely to each other. This proximity is achieved by isolating nanosheets for the P-type transistor from those for the N-type transistor by a dielectric wall. Additionally, an integrated circuit may include a bipolar junction transistor as well as a FET such as a complementary field effect transistor (CFET), a negative capacitance field effect transistor (NCFET), or a carbon nanotube (CNT) FET.

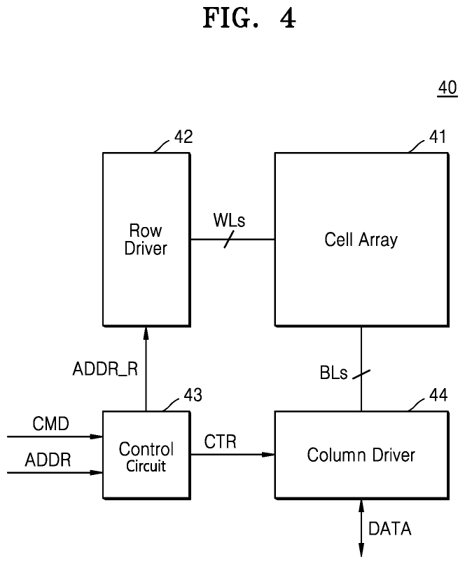

FIG. 4 is a block diagram illustrating a memory device 40 included in an integrated circuit according to an embodiment.

Referring to FIG. 4, the memory device 40 may include a cell array 41, a row driver 42, a control circuit 43, and a column driver 44. In this case, the row driver 42, the control circuit 43, and the column driver 44 may be collectively referred to as a peripheral circuit. According to embodiments, the peripheral circuit may further include a command buffer, an address buffer, a voltage generator, or a data input/output circuit.

The memory device 40 may receive a command CMD, an address ADDR, and data DATA. For example, the memory device 40 may receive a write command CMD, an address ADDR, and data DATA and store the received data DATA in an area of the cell array 41 corresponding to the address ADDR. Additionally, the memory device 40 may receive a read command CMD and an address ADDR and externally output data stored in an area of the cell array 41 corresponding to the address ADDR.

The cell array 41 may include a plurality of memory cells each accessed by a word line and a bit line. According to embodiments, the memory cells may be referred to as bit cells or cells. In some embodiments, the memory cells included in the cell array 41 may be volatile memory cells such as static random access memory (SRAM) cells and dynamic random access memory (DRAM) cells. In some embodiments, the memory cells included in the cell array 41 may be nonvolatile memory cells such as flash memory cells or resistive random access memory (RRAM) cells. As described below with reference to FIG. 6 and the like, embodiments are described mainly with reference to an SRAM cell; however, the inventive concept is not limited thereto.

The control circuit 43 may generate a row address ADDR_R and a control signal CTR based on the command CMD and the address ADDR. For example, the control circuit 43 may identify a read command by decoding the command CMD and may generate a row address ADDR_R and a control signal CTR to read data DATA from the cell array 41. Additionally, the control circuit 43 may identify a write command by decoding the command CMD and may generate a row address ADDR_R and a control signal CTR to write data DATA into the cell array 41.

The row driver 42 may be connected to the cell array 41 through a plurality of word lines WLs and may activate a word line among the plurality of word lines WLs according to the row address ADDR_R. Accordingly, memory cells connected to the activated word line may be selected among the memory cells included in the cell array 41. The column driver 44 may be connected to the cell array 41 through a plurality of bit lines BLs and may perform a read operation or a write operation according to the control signal CTR. For example, at the timing determined based on the control signal CTR, the column driver 44 may sense a current and/or a voltage in the plurality of bit lines BLs or apply a current and/or a voltage to the plurality of bit lines BLs.

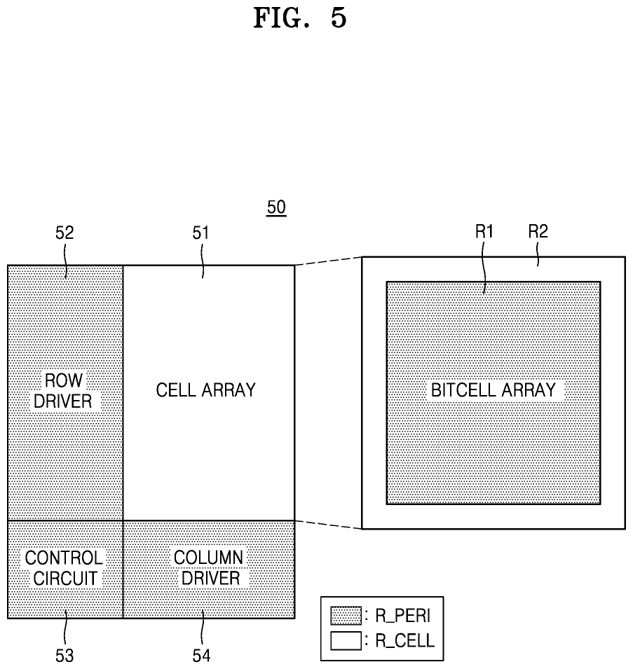

FIG. 5 is a plan view illustrating a layout 50 of an integrated circuit according to an embodiment.

Referring to FIG. 5, the layout 50 may include at least one cell array in a cell array area R_CELL and include a peripheral circuit in a peripheral area R_PERI. For example, the layout 50 may represent a layout of an integrated circuit corresponding to the memory device 40 of FIG. 4. For example, a cell array 51 may be included in the cell array area R_CELL, and a row driver 52, a control circuit 53, and a column driver 54 may be included in the peripheral area R_PERI. The cell array area R_CELL may include a cell area R1 and a dummy area R2, and a bit cell array including a plurality of cells may be arranged in the cell area R1. The description of the cell area R1 and the dummy area R2 given above with reference to FIGS. 1 and 2 may also be applied to the present embodiment.

FIG. 6 is a circuit diagram illustrating a cell array 60 according to an embodiment.

Referring to FIG. 6, the cell array 60 may include memory cells C11, C12, C21, and C22 arranged adjacent to each other. For example, the cell array 60 may correspond to an example of the cell array 41 of FIG. 4 and/or the cell array 51 of FIG. 5. For example, the cell array 60 may be arranged in the cell area R1 of FIG. 1. The memory cell C11 and the memory cell C12 arranged in the same row may be commonly connected to a word line WL[k], and the memory cell C21 and the memory cell C22 arranged in the same row may be commonly connected to a word line WL[k+1] (where k is an integer greater than 0). Additionally, the memory cell C11 and the memory cell C21 arranged in the same column may be connected to a first bit line BL1 and a first complementary bit line BLB1, and the memory cell C12 and the memory cell C22 arranged in the same column may be connected to a second bit line BL2 and a second complementary bit line BLB2.

The memory cell C11 may include a first PFET P11, a second PFET P12, and first, second, third and fourth NFETs N11, N12, N13 and N14 and may be a six-transistor (6T) SRAM cell. The memory cell C11 may include a pair of inverters that are cross-coupled between a node to which a positive supply voltage (or cell voltage) VDD is applied and a node to which a negative supply voltage (or ground voltage) VSS is applied. For example, among the pair of cross-coupled inverters, a first inverter may include the first PFET P11 and the first NFET N11 and a second inverter may include the second PFET P12 and the second NFET N12.

Additionally, the third NFET N13 and the fourth NFET N14 may be referred to as transmission transistors or pass transistors configured to respectively connect the first inverter and the second inverter to the first bit line BL1 and the first complementary bit line BLB1 by the word line WL[k] that is activated (e.g., having a high-level voltage). As illustrated in FIG. 6, the memory cells C12, C21, and C22 may have the same structure as the memory cell C11, and accordingly, the description of the memory cell C11 may be similarly applied to the memory cells C12, C21, and C22.

The memory cell C12 may include a first PFET P21, a second PFET P22, and first, second, third and fourth NFETs N21, N22, N23 and N24. The third NFET N23 and the fourth NFET N24 may be configured to respectively connect a first inverter including the first PFET P21 and the first NFET N21 and a second inverter including the second PFET P22 and the second NFET N22 to the second bit line BL2 and the second complementary bit line BLB2 by the activated word line WL[k].

The memory cell C21 may include a first PFET P31, a second PFET P32, and first, second, third and fourth NFETs N31, N32, N33 and N34. The third NFET N33 and the fourth NFET N34 may be configured to respectively connect a first inverter including the first PFET P31 and the first NFET N31 and a second inverter including the second PFET P32 and the second NFET N32 to the first bit line BL1 and the first complementary bit line BLB1 by the activated word line WL[k+1].

The memory cell C22 may include a first PFET P41, a second PFET P42, and first, second, third and fourth NFETs N41, N42, N43 and N44. The third NFET N43 and the fourth NFET N44 may be configured to respectively connect a first inverter including the first PFET P41 and the first NFET N41 and a second inverter including the second PFET P42 and the second NFET N42 to the second bit line BL2 and the second complementary bit line BLB2 by the activated word line WL[k+1].

If a voltage drop occurs at the node where the cell voltage VDD is applied or the node where the ground voltage VSS is applied, the memory cell C11 may not reliably output a signal that corresponds to a value latched by the pair of cross-coupled inverters, to the first bit line BL1 and the first complementary bit line BLB1. Additionally, the memory cell C11 may not reliably latch a value that corresponds to a signal applied to the first bit line BL1 and the first complementary bit line BLB1, using the pair of cross-coupled inverters. Furthermore, as the number of memory cells included in one row increases, the word line WL[k] may be extended and the influence of the parasitic resistance of the word line WL[k] may increase. Accordingly, the memory cell distant from the row driver 42 of FIG. 4 may identify the activation of the word line at a delayed point in time, and the operation speed of the memory device 40 of FIG. 4 may be restricted. Therefore, a scheme for preventing or reducing a voltage drop with respect to the cell voltage VDD or the ground voltage VSS is required.

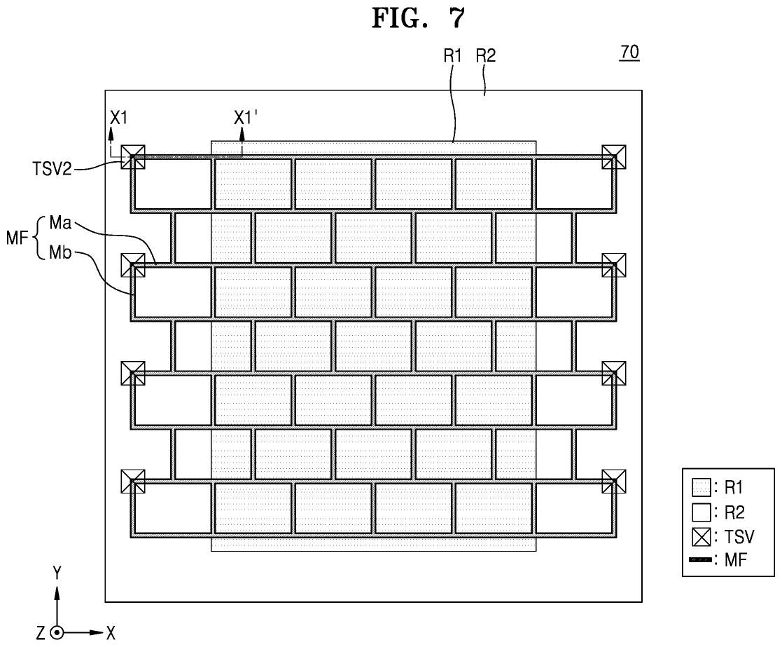

FIG. 7 illustrates a layout of an integrated circuit 70 according to an embodiment.

Referring to FIG. 7, the integrated circuit 70 may correspond to a modification of the integrated circuit 10 of FIG. 1, and the description given above with reference to FIG. 1 may also be applied to the present embodiment. The integrated circuit 70 may include a front-side wiring layer MF arranged over a cell area R1 and a dummy area R2 in the vertical direction Z, and the front-side wiring layer MF may include first patterns Ma extending in the first direction X and second patterns Mb extending in the second direction Y.

The integrated circuit 70 may further include a plurality of through vias TSV arranged in the dummy area R2. In an embodiment, the plurality of through vias TSV may include through vias TSV2 overlapping an area where the first pattern Ma and the second pattern Mb contact each other, in other words, a contact between the first pattern Ma and the second pattern Mb, in the vertical direction Z. For example, the through vias TSV2 may be arranged in a line in the second direction Y; however, the inventive concept is not limited thereto. The number and arrangement of through vias TSV2 may be variously modified according to embodiments. The integrated circuit 70 may further include a back-side wiring layer connected to the through vias TSV2, and the arrangement and/or extension direction of the back-side wiring layer may be variously modified according to embodiments.

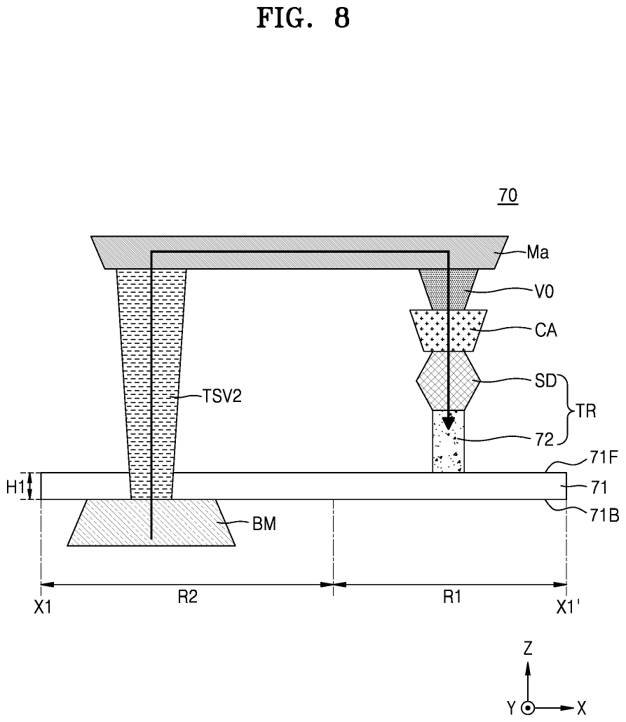

FIG. 8 is a cross-sectional view taken along line X1-X1′ of FIG. 7 according to an embodiment.

Referring to FIGS. 7 and 8, the integrated circuit 70 may include a substrate 71 including a cell area R1 and a dummy area R2. For example, the substrate 71 may include a group IV semiconductor such as Si or Ge, a group IV-IV compound semiconductor such as SiGe or SIC, or a group III-V compound semiconductor such as GaAs, InAs, or InP. In an embodiment, the substrate 71 may be a bulkless substrate having a first height H1. The bulkless substrate is described below in detail.

A transistor TR may be arranged on a front surface 71F of the substrate 71, and the transistor TR may include an active pattern 72 and a source/drain area SD. For example, the transistor TR may correspond to the first NFET N11 or the second NFET N12 included in the memory cell C11 of FIG. 6. For example, the active pattern 72 may correspond to the NFET area R_NFET of FIG. 2, and in this case, the transistor TR may correspond to an NFET. However, the inventive concept is not limited thereto; for example, the active pattern 72 may correspond to the PFET area R_PFET of FIG. 2, and in this case, the transistor TR may correspond to a PFET. A contact CA may be arranged over the source/drain area SD, and a via V0 may be arranged over the contact CA.

A front-side wiring layer MF including patterns for signal routing and/or power may be arranged over the front surface 71F of the substrate 71, and the front-side wiring layer MF may include a first pattern Ma extending in the first direction X across the cell area R1 and the dummy area R2. The first pattern Ma may be connected to the source/drain area SD of the transistor TR through the via V0 and the contact CA. Upper wiring layers and via layers between the upper wiring layers may be further arranged over the front-side wiring layer MF A back-side wiring layer BM may be arranged on a rear surface or back surface 71B of the substrate 71. For example, the back-side wiring layer BM may extend in the first direction X or the second direction Y. Additionally, lower wiring layers and via layers between the lower wiring layers may be further arranged under the back-side wiring layer BM.

The back-side wiring layer BM may be used to provide a negative supply voltage or a positive supply voltage to an element. For example, as illustrated in FIG. 2, the back-side wiring layer BM may provide a negative supply voltage to the NFETs formed in the NFET areas R_NFET. Accordingly, a negative supply voltage may be provided to the NFET from the back-side wiring layer BM through the through via TSV2, the first pattern Ma, the via V0, and the contact CA. For example, as illustrated in FIG. 2, the back-side wiring layer BM may provide a positive supply voltage to the PFETs formed in the PFET areas R_PFET. Accordingly, a positive supply voltage may be provided to the PFET from the back-side wiring layer BM through the through via TSV2, the first pattern Ma, the via V0, and the contact CA. As such, patterns formed on the back-side wiring layer BM to supply power to elements may be referred to as a back-side power rail (BSPR).

According to an embodiment, in a process of manufacturing the integrated circuit 70, a device layer including a transistor TR or the like may be formed on the front surface 71F of the substrate 71, and a plurality of wiring layers and via layers such as a first pattern Ma, a via V0, and a through via TSV2 may be formed over the device layer, thereby forming a device wafer. Subsequently, the device wafer may be temporarily bonded to a carrier wafer, and a back-grinding process may be performed on the device wafer. Since a portion of the substrate 71 is removed by the back-grinding process, the substrate 71 may have a first height H1 in the vertical direction Z. Subsequently, a plurality of wiring layers and via layers including a back-side wiring layer BM may be formed on the rear surface 71B of the substrate 71, and the carrier wafer may be removed. However, the inventive concept is not limited thereto, and the formation time of the through via TSV2 may be variously modified according to the manufacturing process of the integrated circuit 70.

For example, in the process of forming an N-well on a P-type bulk silicon substrate, latch-up can occur. This is often due to the presence of parasitic elements such as diodes, Bipolar Junction Transistors (BJTs), resistances, or similar components existing at the junction between the P-type bulk silicon substrate and the N-well. Such latch-up events can lead to a malfunction of a chip including an integrated circuit. To prevent the latch-up, a ground voltage may be applied to the P-type bulk silicon substrate and a power supply voltage may be applied to the N-well. This may prevent the parasitic diode from being forward-biased or the parasitic BJT from being turned on. In this case, a first power line for applying a ground voltage to the P-type bulk silicon substrate and a second power line for applying a power supply voltage to the N-well are required.

However, according to embodiments, by back-grinding the substrate 71 such that the height of the substrate 71 is equal to or less than a reference height, for example, a first height H1, a parasitic diode or a parasitic BJT may not be formed on the substrate 71, and thus, a latch-up may not occur. As such, a wafer obtained by back-grinding the substrate 71 such that the height of the substrate 71 is equal to or less than the reference height may be referred to as a “bulkless wafer” or a “bulkless substrate”. In the case of a bulkless substrate, in other words, the substrate 71, because a latch-up does not occur, the first and second power lines described above may not be arranged over the dummy area R2. Thus, the freedom of routing may increase in an area over the dummy area R2, and accordingly, some patterns and/or some lines included in the front-side wiring layer MF may be arranged over the dummy area R2 as well as over the cell area R1.

According to the present embodiment, the mesh-shaped front-side wiring layer MF including the first patterns Ma and the second patterns Mb may extend from an area over the cell area R1 to an area over the dummy area R2. Thus, the back-side wiring layer BM arranged in the dummy area R2 may be directly connected to the mesh-shaped front-side wiring layer MF through the through via TSV2 In this case, because the power supply voltage or the ground voltage applied to the back-side wiring layer BM may be directly transmitted to the source/drain area SD of the transistor TR of the cell area R1 without bypass, an IR drop may be reduced. Accordingly, the power supply voltage or the ground voltage applied to the back-side wiring layer BM may be stably supplied to the transistor TR of the cell area R1.

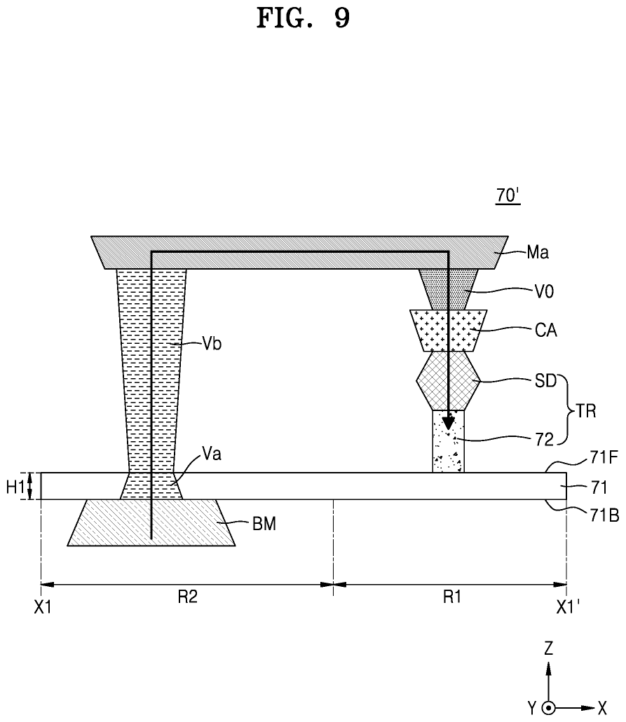

FIG. 9 is a cross-sectional view taken along line X1-X1′ of FIG. 7 according to an embodiment.

Referring to FIGS. 7 and 9, an integrated circuit 70′ may correspond to a modification of the integrated circuit 70 of FIG. 8, and the description given above with reference to FIG. 8 may also be applied to the present embodiment. The integrated circuit 70′ may include a through via Va passing through the dummy area R2 and a via Vb connecting the through via Va to the first pattern Ma. The upper surface of the through via Va may be at the same level as the upper surface of the substrate 71, and the lower surface of the through via Va may be connected to the back-side wiring layer BM. The upper surface of the via Vb may be connected to the lower surface of the first pattern Ma, and the lower surface of the via Vb may be at the same level as the upper surface of the substrate 71. The lower surface of the via Vb may be in contact with the upper surface of the through via Va.

For example, in a process of manufacturing the integrated circuit 70′, a device layer including a transistor TR or the like may be formed on the front surface 71F of the substrate 71, and a plurality of wiring layers and via layers such as a first pattern Ma, a via Vb, and a via V0 may be formed over the device layer, thereby forming a device wafer. Subsequently, the device wafer may be temporarily bonded to a carrier wafer, and a back-grinding process may be performed on the device wafer. Subsequently, a through via Va passing through the substrate 71 may be formed, a plurality of wiring layers and via layers including a back-side wiring layer BM may be formed on the rear surface 71B of the substrate 71, and the carrier wafer may be removed. However, the inventive concept is not limited thereto, and the formation time of the through via Va and the via Vb may be variously modified according to the manufacturing process of the integrated circuit 70′.

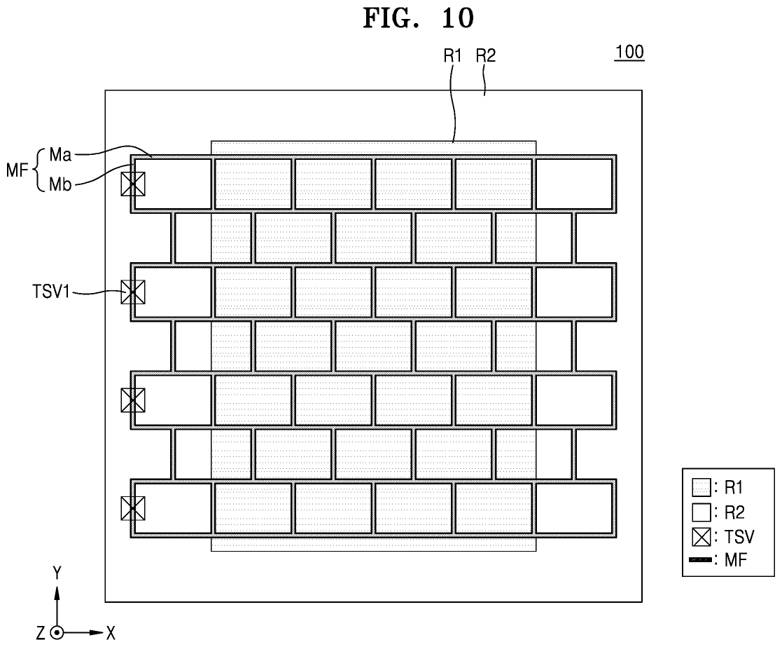

FIG. 10 illustrates a layout of an integrated circuit 100 according to an embodiment.

Referring to FIG. 10, the integrated circuit 100 may correspond to a modification of the integrated circuit 10 of FIG. 1 or the integrated circuit 70 of FIG. 7, and the description given above with reference to FIGS. 1 to 9 may also be applied to the present embodiment. The dummy area R2 may include a first area (e.g., a left area) adjacent to a first edge of the cell area R1 in the first direction X, a second area (e.g., a right area) adjacent to a second edge of the cell area R1 in the first direction X, a third area (e.g., a top area) adjacent to a third edge of the cell area R1 in the second direction Y, and a fourth area (e.g., a bottom area) adjacent to a fourth edge of the cell area R1 in the second direction Y.

The integrated circuit 100 may include a plurality of through vias TSV arranged in at least one of the first to fourth areas of the dummy area R2. For example, the plurality of through vias TSV may include through vias TSV1 overlapping the second patterns Mb of the front-side wiring layer MF in the vertical direction Z and arranged in a line in the second direction Y. In this case, the number of through vias TSV1 may be variously modified according to embodiments. In an embodiment, the through vias TSV1 may be arranged only in the first area of the dummy area R2. However, the inventive concept is not limited thereto, and the through vias TSV1 may be arranged only in the second area of the dummy area R2. In another embodiment, the through vias TSV1 may be arranged in both the first and second areas of the dummy area R2.

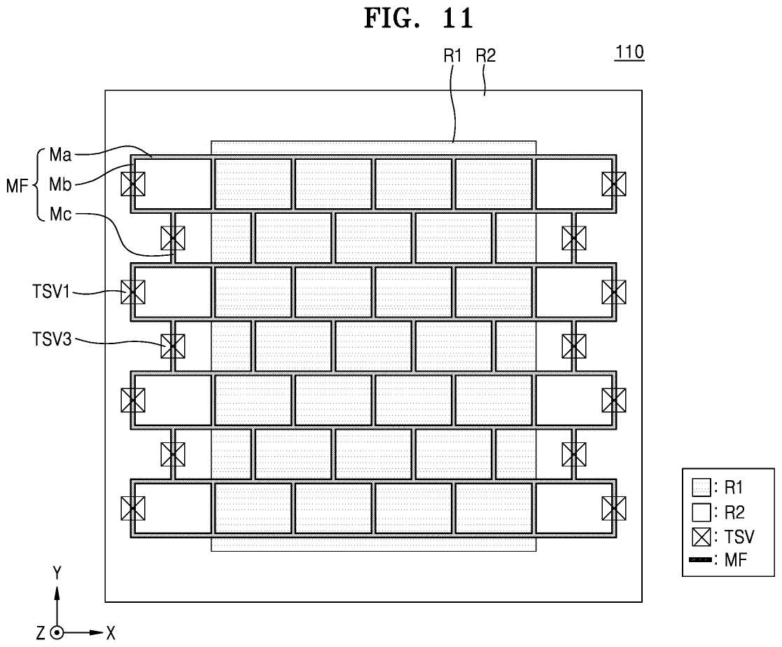

FIG. 11 illustrates a layout of an integrated circuit 110 according to an embodiment.

Referring to FIG. 11, the integrated circuit 110 may correspond to a modification of the integrated circuit 10 of FIG. 1 or the integrated circuit 70 of FIG. 7, and the description given above with reference to FIGS. 1 to 9 may also be applied to the present embodiment. The integrated circuit 110 may include a front-side wiring layer MF including first patterns Ma extending in the first direction X, second patterns Mb extending in the second direction Y, and third patterns Mc extending in the second direction Y. In this case, the second patterns Mb and the third patterns Mc may be spaced apart from each other in the first direction X. The second patterns Mb may be connected between a pair of adjacent first patterns Ma and the third patterns Mc may be connected between adjacent pairs of the first patterns Ma.

The integrated circuit 110 may include through vias TSV1 respectively overlapping the second patterns Mb arranged over the dummy area R2, in the vertical direction Z, and through vias TSV3 respectively overlapping the third patterns Mc arranged over the dummy area R2, in the vertical direction Z. For example, the through vias TSV1 may be arranged in a line in the second direction Y; however, the inventive concept is not limited thereto. For example, the through vias TSV3 may be arranged in a line in the second direction Y; however, the inventive concept is not limited thereto. In this case, the number of through vias TSV1 and TSV3 may be variously modified according to embodiments. In some embodiments, the through vias TSV1 and TSV3 may be arranged only in a portion of the dummy area R2, for example, only in the left area adjacent to the cell area R1 in the first direction X. In some embodiments, the through vias TSV1 and TSV3 may be arranged only in a portion of the dummy area R2, for example, only in the right area adjacent to the cell area R1 in the first direction X.

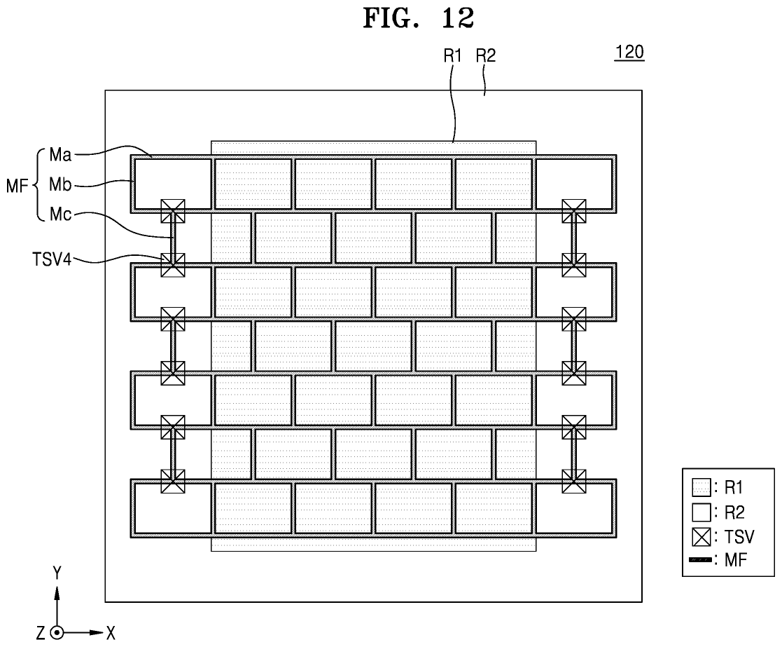

FIG. 12 illustrates a layout of an integrated circuit 120 according to an embodiment.

Referring to FIG. 12, the integrated circuit 120 may correspond to a modification of the integrated circuit 10 of FIG. 1 or the integrated circuit 70 of FIG. 7, and the description given above with reference to FIGS. 1 to 9 may also be applied to the present embodiment. The integrated circuit 120 may include a front-side wiring layer MF including first patterns Ma extending in the first direction X, second patterns Mb extending in the second direction Y, and third patterns Mc extending in the second direction Y. In this case, the second patterns Mb and the third patterns Mc may be spaced apart from each other in the first direction X.

The integrated circuit 120 may include through vias TSV4 respectively overlapping the junction areas of the patterns arranged over the dummy area R2, in the vertical direction Z. For example, the through via TSV4 may overlap an area where the first pattern Ma and the third pattern Mc contact each other, in other words, a contact between the first pattern Ma and the third pattern Mc, in the vertical direction Z. For example, the through vias TSV4 may be arranged in a line in the second direction Y; however, the inventive concept is not limited thereto. In this case, the number of through vias TSV4 may be variously modified according to embodiments. In some embodiments, the through vias TSV4 may be arranged only in a portion of the dummy area R2, for example, only in the left area adjacent to the cell area R1 in the first direction X. In some embodiments, the through vias TSV4 may be arranged only in a portion of the dummy area R2, for example, only in the right area adjacent to the cell area R1 in the first direction X.

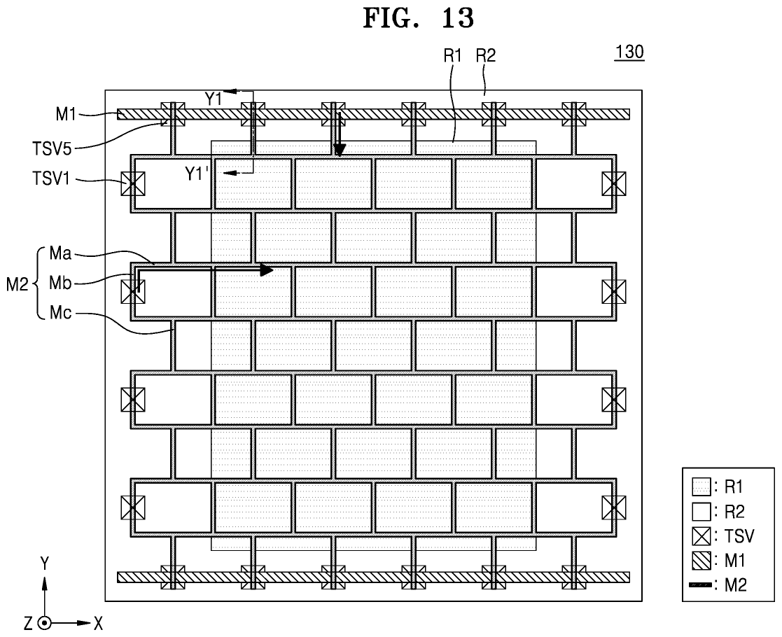

FIG. 13 illustrates a layout of an integrated circuit 130 according to an embodiment.

Referring to FIG. 13, the integrated circuit 130 may include a first front-side wiring layer M1 extending in the first direction X and a second front-side wiring layer M2 arranged over the first front-side wiring layer M1. For example, the second front-side wiring layer M2 may correspond to the front-side wiring layer MF of FIG. 1 and may include first patterns Ma extending in the first direction X and second and third patterns Mb and Mc extending in the second direction Y. In this case, a first front-side wiring layer M1 may be further arranged between the second front-side wiring layer M2 and the cell area R1, and accordingly, the second front-side wiring layer M2 may be connected to a plurality of cells included in the cell area R1 through the first front-side wiring layer M1. More specifically, the third patterns Mc of the second front-side wiring layer M2 may extend in the second direction Y from the cell area R1 (as well as the dummy area R2) to overlap with the first front-side wiring layer M1 in the dummy area R2. Additionally, a first front-side wiring layer M1 including a plurality of front wiring patterns (e.g., a plurality of island patterns) may be further arranged between the second front-side wiring layer M2 and the dummy area R2.

The integrated circuit 130 may include a plurality of through vias TSV arranged in the dummy area R2 and connected to a back-side wiring layer. The plurality of through vias TSV may include through vias TSV1 respectively overlapping the second patterns Mb of the second front-side wiring layer M2 in the vertical direction Z, and through vias TSV5 respectively overlapping the first front-side wiring layer M1 in the vertical direction Z. For example, the through vias TSV1 may be arranged in a line in the second direction Y; however, the inventive concept is not limited thereto. For example, the through vias TSV5 may be arranged in a line in the first direction X; however, the inventive concept is not limited thereto. In this case, the number of through vias TSV1 and TSV5 may be variously modified according to embodiments.

According to embodiments, the plurality of through vias TSV may further include the through vias TSV2 of FIG. 7, the through vias TSV3 of FIG. 11, and/or the through vias TSV4 of FIG. 12. In some embodiments, the through vias TSV5 may be arranged only in a portion of the dummy area R2, for example, only in the top area adjacent to the cell area R1 in the second direction Y. In some embodiments, the through vias TSV5 may be arranged only in a portion of the dummy area R2, for example, only in the bottom area adjacent to the cell area R1 in the second direction Y.

FIG. 14 is a cross-sectional view taken along line Y1-Y1′ of FIG. 13 according to an embodiment.

Referring to FIGS. 13 and 14, the integrated circuit 130 may correspond to a modification of the integrated circuit 70 of FIG. 8, and the description given above with reference to FIG. 8 may also be applied to the present embodiment. The integrated circuit 130 may include a substrate 131 including a cell area R1 and a dummy area R2. A transistor TR may be arranged on a front surface 131F of the substrate 131, and the transistor TR may include an active pattern 132 and a source/drain area SD. A contact CA may be arranged over the source/drain area SD, and a via V0 may be arranged over the contact CA.

A first front-side wiring layer M1 and a second front-side wiring layer M2 including patterns for signal routing and/or power may be arranged over the front surface 131F of the substrate 131. The first front-side wiring layer M1 may include a first wiring pattern M1a over the cell area R1 and a second wiring pattern M1b over the dummy area R2. The first wiring pattern M1a and the second wiring pattern M1b may be located as the same level as each other. A via V1a may be arranged over the first wiring pattern M1a, and a via V1b may be arranged over the second wiring pattern M1b. The vias V1a and V1b may be located at the same level as each other. The second front-side wiring layer M2 may be connected to the first and second wiring patterns M1a and M1b through the vias V1a and V1b.

A back-side wiring layer BM may be arranged on a rear surface 131B of the substrate 131. For example, the back-side wiring layer BM may extend in the first direction X or the second direction Y. Additionally, lower wiring layers and via layers between the lower wiring layers may be further arranged under the back-side wiring layer BM. The back-side wiring layer BM may be used to provide a negative supply voltage or a positive supply voltage to an element. The through via TSV5 may extend in the vertical direction Z and connect the back-side wiring layer BM to the second wiring pattern M1b.

According to an embodiment, in a process of manufacturing the integrated circuit 130, a device layer including a transistor TR or the like may be formed on the front surface 131F of the substrate 131, and a through via TSV5, a contact CA, a via V0, first and second wiring patterns M1a and M1b, vias V1a and V1b, and a second front-side wiring layer M2 may be formed over the device layer, thereby forming a device wafer. Subsequently, the device wafer may be temporarily bonded to a carrier wafer, and a back-grinding process may be performed on the device wafer. Since a portion of the substrate 131 of the device wafer is removed by the back-grinding process, the substrate 131 may have a first height H1 in the vertical direction Z. Subsequently, a back-side wiring layer BM may be formed on the rear surface 131B of the substrate 131, and the carrier wafer may be removed.

According to embodiments, by back-grinding the substrate 131 such that the height of the substrate 131 is equal to or less than a reference height, for example, a first height H1, a parasitic diode or a parasitic BJT may not be formed on the bulkless substrate, in other words, the substrate 131, and thus, a latch-up may not occur. Accordingly, in the case of the substrate 131, the first and second power lines described above may not be arranged over the dummy area R2. Thus, the freedom of routing may increase in an area over the dummy area R2, and accordingly, some patterns and/or some lines included in the second front-side wiring layer M2 may be arranged over the dummy area R2 as well as over the cell area R1.

According to the present embodiment, the mesh-shaped second front-side wiring layer M2 including the first patterns Ma and the second patterns Mb may extend from a location over the cell area R1 to a location over the dummy area R2. Thus, the back-side wiring layer BM arranged in the dummy area R2 may be directly connected to the mesh-shaped second front-side wiring layer M2 through the through vias TSV1 and TSV5. In this case, because the power supply voltage or the ground voltage applied to the back-side wiring layer BM may be directly transmitted to the source/drain area SD of the transistor TR of the cell area R1 without bypass, an IR drop may be reduced. Accordingly, the power supply voltage or the ground voltage applied to the back-side wiring layer BM may be stably supplied to the transistor TR of the cell area R1.

In an embodiment, the integrated circuit 130 may further include a third front-side wiring layer over the second front-side wiring layer M2 in the vertical direction Z. For example, a first supply voltage (e.g., a ground voltage) may be applied to the back-side wiring layer BM, and the first supply voltage may be supplied to each of the plurality of cells of the cell area R1. In this case, the first supply voltage may be applied to the plurality of cells of the cell area R1 through the back-side wiring layer BM, the second wiring pattern M1b, the second front-side wiring layer M2, and the first wiring pattern M1a. For example, a second supply voltage (e.g., a power supply voltage) may be applied to the third front-side wiring layer, and the second supply voltage may be supplied to each of the plurality of cells of the cell area R1. In this case, the second supply voltage may be applied to the plurality of cells of the cell area R1 through the third front-side wiring layer, the second front-side wiring layer M2, and the first front-side wiring layer M1.

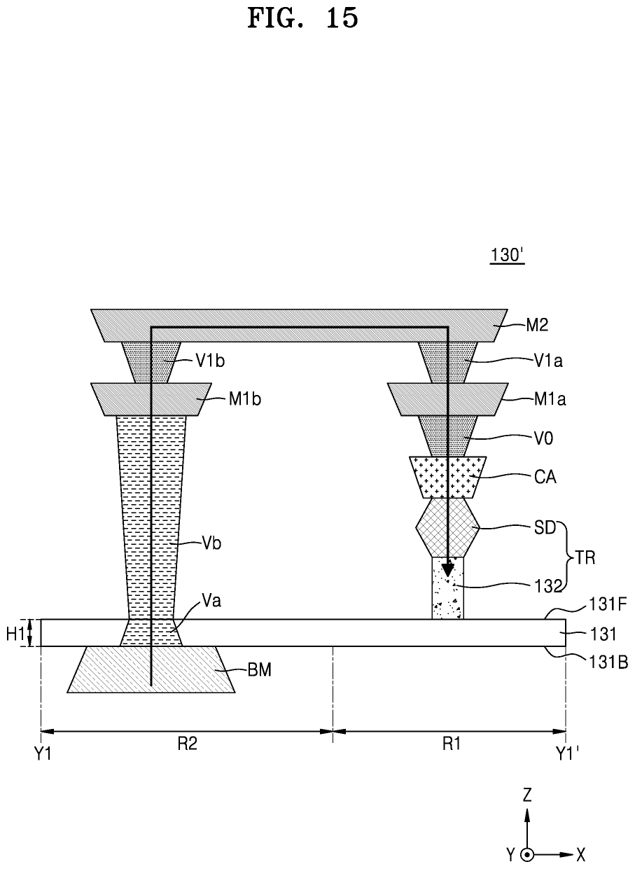

FIG. 15 is a cross-sectional view taken along line Y1-Y1′ of FIG. 13 according to an embodiment.

Referring to FIGS. 13 and 15, an integrated circuit 130′ may correspond to a modification of the integrated circuit 130 of FIG. 14, and the description given above with reference to FIG. 14 may also be applied to the present embodiment. The integrated circuit 130′ may include a through via Va passing through the dummy area R2 and a via Vb connecting the through via Va to the second wiring pattern M1b. The upper surface of the through via Va may be at the same level as the upper surface of the substrate 131, and the lower surface of the through via Va may be connected to the back-side wiring layer BM. For example, the lower surface of the through via Va may be in direct contact with the upper surface of the back-side wiring layer BM. The upper surface of the via Vb may be connected to the lower surface of the second wiring pattern M1b, and the lower surface of the via Vb may be at the same level as the upper surface of the substrate 131.

For example, in a process of manufacturing the integrated circuit 130′, a device layer including a transistor TR or the like may be formed on the front surface 131F of the substrate 131, and a via Vb, a contact CA, a via V0, first and second wiring patterns M1a and M1b, vias V1a and V1b, and a second front-side wiring layer M2 may be formed over the device layer, thereby forming a device wafer. Subsequently, the device wafer may be temporarily bonded to a carrier wafer, and a back-grinding process may be performed on the device wafer. Subsequently, a through via Va passing through the substrate 131 may be formed, a back-side wiring layer BM may be formed on the rear surface 131B of the substrate 131, and the carrier wafer may be removed. However, the inventive concept is not limited thereto, and the formation time of the through via Va and the via Vb may be variously modified according to the manufacturing process of the integrated circuit 130′.

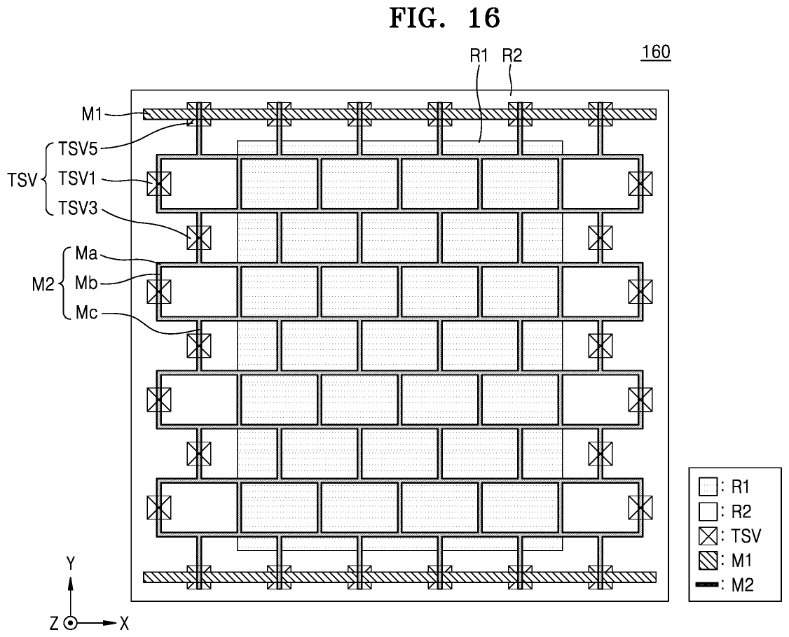

FIG. 16 illustrates a layout of an integrated circuit 160 according to an embodiment.

Referring to FIG. 16, the integrated circuit 160 may correspond to a modification of the integrated circuit 130 of FIG. 13, and the description given above with reference to FIGS. 13 to 15 may also be applied to the present embodiment. The integrated circuit 160 may include a plurality of through vias TSV connected to the back-side wiring layer BM in the dummy area R2. The plurality of through vias TSV may include through vias TSV1 respectively overlapping the second patterns Mb of the second front-side wiring layer M2 arranged over the dummy area R2, in the vertical direction Z, through vias TSV5 overlapping the first front-side wiring layer M1 arranged over the dummy area R2, in the vertical direction Z, and through vias TSV3 respectively overlapping the third patterns Mc of the second front-side wiring layer M2 arranged over the dummy area R2, in the vertical direction Z. For example, the through vias TSV1 may be arranged in a line in the second direction Y; however, the inventive concept is not limited thereto. For example, the through vias TSV3 may be arranged in a line in the second direction Y; however, the inventive concept is not limited thereto. For example, the through vias TSV5 may be arranged in a line in the first direction X; however, the inventive concept is not limited thereto. In this case, the number of through vias TSV1, TSV3, and TSV5 may be variously modified according to embodiments.

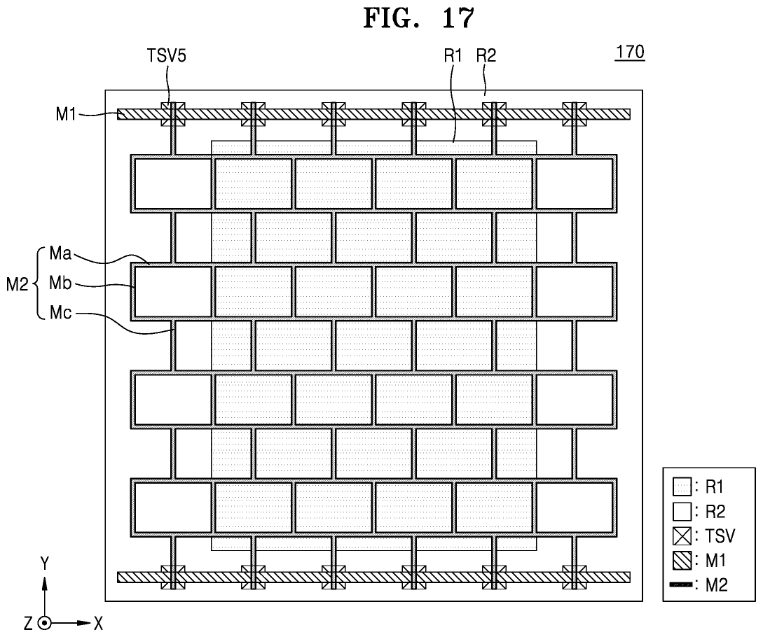

FIG. 17 illustrates a layout of an integrated circuit 170 according to an embodiment.

Referring to FIG. 17, the integrated circuit 170 may correspond to a modification of the integrated circuit 130 of FIG. 13, and the description given above with reference to FIGS. 13 to 15 may also be applied to the present embodiment. The integrated circuit 170 may include through vias TSV5 arranged to overlap the first front-side wiring layer M1 arranged over the dummy area R2, in the vertical direction Z. For example, the through vias TSV5 may be arranged in a line in the first direction X; however, the inventive concept is not limited thereto. In this case, the number of through vias TSV5 may be variously modified according to embodiments. Unlike that shown in FIG. 13, through vias TSV1 may not be provided on the second patterns Mb.

In FIG. 17, the second front-side wiring layer M2 is arranged in a mesh shape; however, the inventive concept is not limited thereto. In some embodiments, the second front-side wiring layer M2 may include lines or patterns extending in the second direction Y across the cell area R1 and the dummy area R2, and the through vias TSV5 may respectively overlap the lines or patterns. In this case, the supply voltage applied to the back-side wiring layer BM may be transmitted to the cell area through the through vias TSV5 and the patterns or lines.

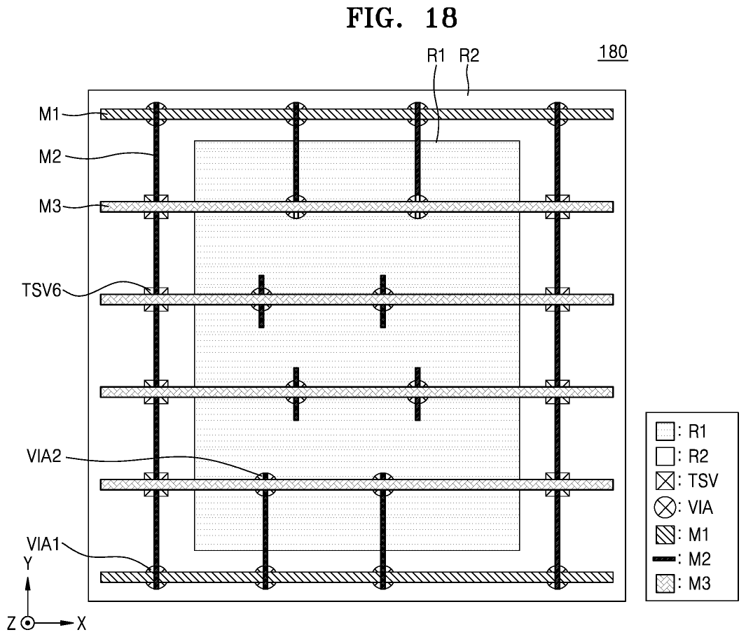

FIG. 18 illustrates a layout of an integrated circuit 180 according to an embodiment.

Referring to FIG. 18, the integrated circuit 180 may include a first front-side wiring layer M1 extending in the first direction X, a second front-side wiring layer M2 extending in the second direction Y and arranged over the first front-side wiring layer M1 in the vertical direction Z, and a third front-side wiring layer M3 extending in the first direction X and arranged over the second front-side wiring layer M2 in the vertical direction Z. The first front-side wiring layer M1 and the third front-side wiring layer M3 may extend in parallel to each other. The integrated circuit 180 may include a plurality of through vias TSV6 arranged in the dummy area R2, and the plurality of through vias TSV6 may overlap the second front-side wiring layer M2 in the vertical direction Z. For example, the through vias TSV6 may be arranged in a line in the second direction Y; however, the inventive concept is not limited thereto. In this case, the number of through vias TSV6 may be variously modified according to embodiments. The integrated circuit 180 may further include a first via VIA1 between the first front-side wiring layer M1 and the second front-side wiring layer M2 and a second via VIA2 between the second front-side wiring layer M2 and the third front-side wiring layer M3.

The voltage applied to the back-side wiring layer may be transmitted to the cell area R1 through the plurality of through vias TSV6, the first front-side wiring layer M1, the first via VIA1, the second front-side wiring layer M2, the second via VIA2, and the third front-side wiring layer M3. In the cell area R1, the third front-side wiring layer M3 may be connected to a transistor through the second via VIA2, the second front-side wiring layer M2, the first via VIA1, and the first front-side wiring layer M1.

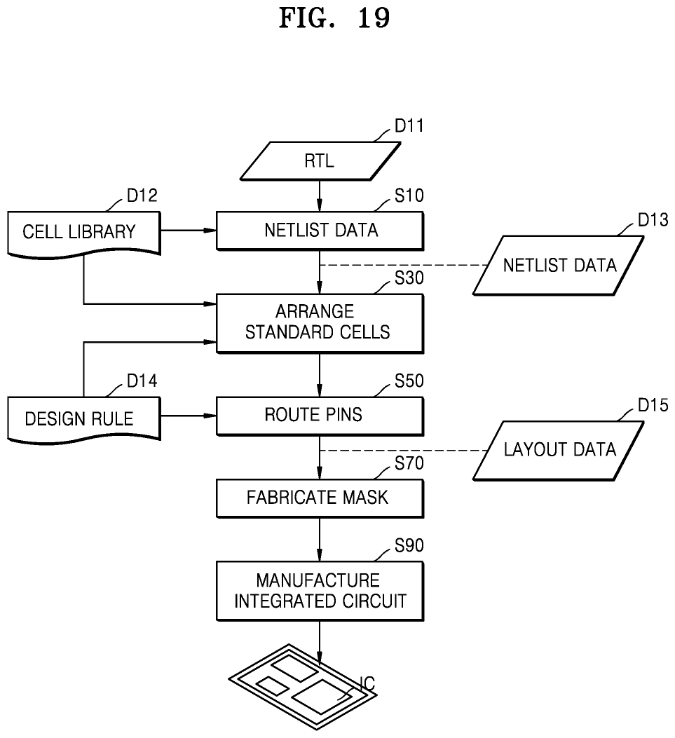

FIG. 19 is a flowchart illustrating a method of manufacturing an integrated circuit IC according to an embodiment.

Referring to FIG. 19, the method according to the present embodiment may be a method of manufacturing an integrated circuit IC including standard cells and may include a plurality of operations S10, S30, S50, S70, and S90. A standard cell may be a unit of a layout included in an integrated circuit and may be designed to perform a predefined function.

A cell library (or a standard cell library) D12 may include information about standard cells, for example, information about functions, characteristics, layouts, and/or the like. In some embodiments, the cell library D12 may define a tab cell and a dummy cell as well as function cells that generate an output signal from an input signal. In some embodiments, the cell library D12 may define memory cells and dummy cells having the same footprint. A design rule D14 may include requirements that the layout of an integrated circuit IC should comply with. For example, the design rule D14 may include requirements for a distance (e.g., a space) between patterns in the same layer, a minimum width of a pattern, a routing direction of a wiring layer, and/or the like. In some embodiments, the design rule D14 may define a minimum spacing in the same track of a wiring layer.

In operation S10, a logic synthesis operation may be performed to generate netlist data D13 from RTL data D11. For example, a semiconductor design tool (e.g., a logic synthesis tool) may perform logic synthesis with reference to the cell library D12 from the RTL data D11 written in VHSIC Hardware Description Language (VHDL) or Hardware Description Language (HDL) such as Verilog and may generate netlist data D13 including a bitstream or a netlist. The netlist data D13 may correspond to an input of place and routing described below.

In operation S30, standard cells may be arranged. For example, with reference to the cell library D12, a semiconductor design tool (e.g., a P&R tool) may arrange the standard cells used in the netlist data D13. In some embodiments, the semiconductor design tool may arrange a standard cell in a row extending in the X-axis direction or the Y-axis direction, and the arranged standard cell may receive power from a power rail extending along the boundaries of the row.

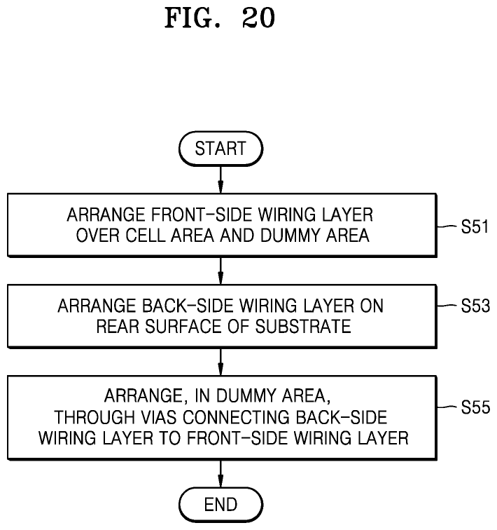

In operation S50, pins of the standard cells may be routed. For example, the semiconductor design tool may generate interconnections electrically connecting output pins and input pins of arranged standard cells and may generate layout data D15 defining the arranged standard cells and the generated interconnections. The interconnections may include a via of a via layer and/or patterns of wiring layers. The wiring layers may include a front-side wiring layer arranged over the front surface of a substrate and a back-side wiring layer arranged on the rear surface of the substrate. The layout data D15 may have a format such as GDSII and may include geometric information of cells and interconnections. The semiconductor design tool may refer to the design rule D14 while routing the pins of the cells. The layout data D15 may correspond to an output of place and routing. An example of operation S50 will be described below with reference to FIG. 20. Operation S50 may alone be or operations S30 and S50 may collectively be referred to as a method of designing an integrated circuit.

In operation S70, a mask may be fabricated. For example, an optical proximity correction (OPC) for correcting a distortion such as refraction caused by the characteristics of light in photolithography may be applied to the layout data D15. Patterns on a mask may be defined to form patterns arranged on a plurality of layers based on the OPC-applied data, and at least one mask (or photomask) for forming patterns of each of the plurality of layers may be fabricated. In some embodiments, the layout of the integrated circuit IC may be restrictively modified in operation S70, and the restrictive modification of the integrated circuit IC in operation S70 may be a postprocessing for optimizing the structure of the integrated circuit IC and may be referred to as design polishing.

In operation S90, an integrated circuit IC may be manufactured. For example, the integrated circuit IC may be manufactured by patterning a plurality of layers by using at least one mask fabricated in operation S70. A front-end-of-line (FEOL) may include, for example, an operation of planarizing and cleaning a wafer, an operation of forming a trench, an operation of forming a well, an operation of forming a gate electrode, and an operation of forming a source and a drain. By the FEOL, individual elements such as transistors, capacitors, and/or resistors may be formed on the substrate. Additionally, a back-end-of-line (BEOL) may include, for example, an operation of silicidating a gate, source and drain area, an operation of adding a dielectric, an operation of planarization, an operation of forming a hole, an operation of adding a metal layer, an operation of forming a via, and an operation of forming a passivation layer. By the BEOL, individual elements such as transistors, capacitors, and/or resistors may be interconnected. In some embodiments, a middle-of-line (MOL) may be performed between the FEOL and the BEOL, and contacts may be formed over the individual elements. Then, the integrated circuit IC may be packaged in a semiconductor package and may be used as a component in various applications.

FIG. 20 is a flowchart illustrating a method of designing an integrated circuit, according to an embodiment.

Referring to FIG. 20, the method according to the present embodiment may represent an example of operation S50 of FIG. 19 and may include operation S51, operation S53, and operation S55. In operation S51, a front-side wiring layer may be arranged over the cell area and the dummy area of the substrate. In an embodiment, the front-side wiring layer may include first patterns or first lines extending from the cell area to the dummy area. In an embodiment, the front-side wiring layer may further include a second pattern arranged in the dummy area and contacting the first pattern. For example, the front-side wiring layer may be arranged in a mesh shape.

In operation S53, a back-side wiring layer may be arranged on the rear surface of the substrate. For example, the semiconductor design tool may use the back-side wiring layer as a routing resource for routing pins. Accordingly, the back-side wiring layer may be used for routing a power pin for power supply as well as the input pin and the output pin of the standard cell. Routing congestion may be eliminated due to an increased routing resource, the interconnection may be simplified, and as a result, the signal path thereof may be shortened.

In operation S55, a through via connecting the back-side wiring layer to the front-side wiring layer may be arranged in the dummy area. For example, the semiconductor design tool may arrange a through via to connect the pattern of the back-side wiring layer generated in operation S53 to the pattern of the front-side wiring layer, for example, the first front-side wiring layer M1 of FIG. 13. However, the inventive concept is not limited thereto, and according to embodiments, operation S55 may be first performed and then operation S53 may be performed.

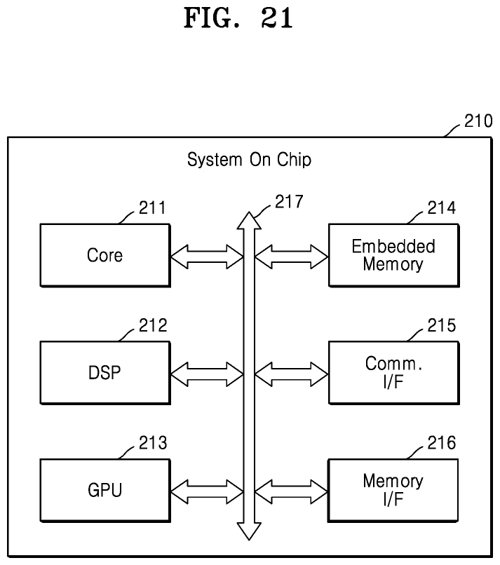

FIG. 21 is a block diagram illustrating a system-on-chip (SoC) 210 according to an embodiment.

Referring to FIG. 21, the SoC 210 may refer to an integrated circuit in which the components of a computing system or other electronic systems are integrated. For example, as an example of the SoC 210, an application processor (AP) may include a processor and components for other functions. The SoC 210 may include a core 211, a digital signal processor (DSP) 212, a graphic processing unit (GPU) 213, an embedded memory 214, a communication interface 215, and a memory interface 216. The components of the SoC 210 may communicate with each other through a bus 217.

The core 211 may process instructions and control an operation of the components included in the SoC 210. For example, by processing a series of instructions, the core 211 may drive an operating system and execute applications on the operating system. The DSP 212 may generate useful data by processing a digital signal, for example, a digital signal provided from the communication interface 215. The GPU 213 may generate data for an image output through a display device, from image data provided from the embedded memory 214 or the memory interface 216 or may encode the image data. In some embodiments, the memory device described above with reference to the drawings may be included as a cache memory and/or a buffer in the core 211, the DSP 212, and/or the GPU 213. Accordingly, due to the high reliability and efficiency of the memory device, the core 211, the DSP 212, and/or the GPU 213 may also have high reliability and efficiency.

The embedded memory 214 may store data necessary for the operation of the core 211, the DSP 212, and the GPU 213. In some embodiments, the embedded memory 214 may include the memory device described above with reference to the drawings. Accordingly, the embedded memory 214 may have a reduced area and high efficiency, and as a result, the operational reliability and efficiency of the SoC 210 may be improved. The communication interface 215 may provide an interface for one-to-one communication or a communication network. The memory interface 216 may provide an interface for an external memory of the SoC 210, such as a dynamic random access memory (DRAM) or a flash memory.

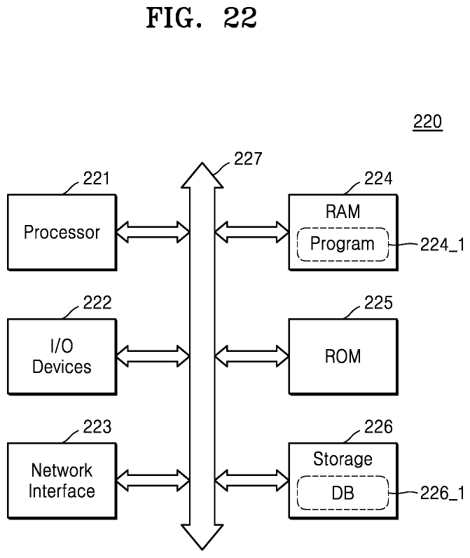

FIG. 22 is a block diagram illustrating a computing system 220 including a memory storing a program according to an embodiment.

Referring to FIG. 22, a method of designing an integrated circuit according to embodiments, for example, at least some of the operations of the flowcharts described above, may be performed in the computing system (or computer) 220. The computing system 220 may be a stationary computing system such as a desktop computer, a workstation, or a server, or a portable computing system such as a laptop computer. The computing system 220 may include a processor 221, input/output devices 222, a network interface 223, a random access memory (RAM) 224, a read only memory (ROM) 225, and a storage device 226. The processor 221, the input/output devices 222, the network interface 223, the RAM 224, the ROM 225, and the storage device 226 may be connected to a bus 227 and may communicate with each other through the bus 227.

The processor 221 may be referred to as a processing unit and may include at least one core capable of executing any instruction set (e.g., Intel Architecture-32 (IA-32), 64-bit extended IA-32, x86-64, PowerPC, Sparc, MIPS, ARM, IA-64, or the like). For example, the processor 221 may access a memory, in other words, the RAM 224 or the ROM 225, through the bus 227 and may execute the instructions stored in the RAM 224 or the ROM 225.

The RAM 224 may store a program 224_1 or at least a portion thereof for a method of designing an integrated circuit according to an embodiment, and the program 224_1 may cause the processor 221 to perform the method of designing the integrated circuit, for example, at least some of the operations included in the method of FIG. 20. In other words, the program 224_1 may include a plurality of instructions executable by the processor 221, and the plurality of instructions included in the program 224_1 may cause the processor 221 to perform, for example, at least some of the operations included in the flowcharts described above.

The storage device 226 may not lose stored data even when power supplied to the computing system 220 is interrupted. For example, the storage device 226 may include a nonvolatile memory device or may include a storage medium such as a magnetic tape, an optical disk, or a magnetic disk. Additionally, the storage device 226 may be detachable from the computing system 220. The storage device 226 may store the program 224_1 according to an embodiment, and the program 224_1 or at least a portion thereof may be loaded from the storage device 226 into the RAM 224 before the program 224_1 is executed by the processor 221. Alternatively, the storage device 226 may store a file written in a program language, and the program 224_1 generated by a compiler or the like from the file or at least a portion thereof may be loaded into the RAM 224. Additionally, the storage device 226 may store a database 226_1, and the database 226_1 may include information used to design an integrated circuit, for example, information about designed blocks and the cell library D12 and/or the design rule D14 of FIG. 19.

The storage device 226 may store data to be processed by the processor 221 or data processed by the processor 221. In other words, according to the program 224_1, the processor 221 may generate data by processing data stored in the storage device 226 and may store the generated data in the storage device 226. For example, the storage device 226 may store the RTL data D11, the netlist data D13, and/or the layout data DIS of FIG. 19.

The input/output devices 222 may include an input device such as a keyboard and/or a pointing device and may include an output device such as a display device and/or a printer. For example, through the input/output devices 222, a user may trigger the execution of the program 224_1 by the processor 221, may input the RTL data D11 and/or the netlist data D13 of FIG. 19, and may identify the layout data DIS of FIG. 19. The network interface 223 may provide access to a network outside the computing system 220. For example, the network may include a plurality of computing systems and communication links, and the communication links may include wired links, optical links, wireless links, or any other types of links.

While the inventive concept has been particularly shown and described with reference to embodiments thereof, it will be understood that various changes in form and detail may be made thereto without departing from the spirit and scope of the inventive concept set forth in the following claims.

What is claimed is:

1. An integrated circuit comprising:
a substrate comprising a cell area and a dummy area, wherein a plurality of cells are arranged in the cell area;
a front-side wiring layer arranged over a front surface of the substrate in a vertical direction, wherein the front-side wiring layer includes a first pattern extending in a first direction across the cell area and the dummy area and a second pattern extending in a second direction intersecting the first direction and contacting the first pattern;
a through via overlapping the front-side wiring layer in the vertical direction in the dummy area and passing through the substrate; and
a back-side wiring layer arranged on a rear surface of the substrate,
wherein the back-side wiring layer is connected through the through via and the front-side wiring layer to at least one transistor included in the plurality of cells.

2. The integrated circuit of claim 1, wherein the front-side wiring layer has a mesh shape.

3. The integrated circuit of claim 1, further comprising a via extending in the vertical direction over the substrate and connected between the through via and the front-side wiring layer.

4. The integrated circuit of claim 1, further comprising a contact connected to a source/drain area of the at least one transistor,
wherein the back-side wiring layer is connected through the through via, the front-side wiring layer, and the contact to the source/drain area of the at least one transistor.

5. The integrated circuit of claim 4, wherein a ground voltage applied to the back-side wiring layer passes through the through via, the front-side wiring layer, and the contact to the source/drain area of the at least one transistor.

6. The integrated circuit of claim 1, further comprising:
a second wiring layer arranged over the dummy area;
a first via over the first pattern of the front-side wiring layer;
a second via over the second pattern of the front-side wiring layer; and
a contact connected to a source/drain area of the at least one transistor,
wherein the back-side wiring layer is connected through the through via, the second pattern, the second via, the second wiring layer, the first via, the first pattern, and the contact to the source/drain area of the at least one transistor.

7. The integrated circuit of claim 1, wherein the first pattern extends in the first direction across the cell area and the dummy area, and
the through via overlaps at least one of the first pattern and the second pattern in the vertical direction.

8. The integrated circuit of claim 1, wherein the through via overlaps a contact between the first pattern and the second pattern in the vertical direction.

9. The integrated circuit of claim 1, wherein the dummy area comprises:
a first area adjacent to a first edge of the cell area in the first direction;
a second area adjacent to a second edge of the cell area in the first direction;
a third area adjacent to a third edge of the cell area in the second direction; and
a fourth area adjacent to a fourth edge of the cell area in the second direction,
wherein the through via is arranged in at least one of the first to fourth areas.

10. An integrated circuit comprising:
a substrate comprising a cell area and a dummy area, wherein the cell area includes a plurality of cells;
a front-side wiring layer arranged over the cell area and the dummy area in a vertical direction, wherein the front-side wiring layer has a mesh shape;
a back-side wiring layer arranged on a rear surface of the substrate; and
a plurality of through vias overlapping the front-side wiring layer in the vertical direction in the dummy area and passing through the substrate,
wherein a voltage applied to the back-side wiring layer passes through the plurality of through vias and the front-side wiring layer to at least one transistor included in the plurality of cells.

11. The integrated circuit of claim 10, wherein the front-side wiring layer comprises:
a plurality of first patterns extending in a first direction across the cell area and the dummy area; and
a plurality of second patterns extending in a second direction crossing the first direction.

12. The integrated circuit of claim 11, wherein the plurality of through vias respectively overlap the plurality of second patterns in the vertical direction and are arranged in a line in the second direction.

13. The integrated circuit of claim 11, wherein the front-side wiring layer further comprises a plurality of third patterns extending in the second direction and respectively spaced apart from the plurality of second patterns in the first direction, and
the plurality of through vias comprise:
a plurality of first through vias respectively overlapping the plurality of second patterns in the vertical direction and arranged in a line in the second direction; and
a plurality of second through vias respectively overlapping the plurality of third patterns in the vertical direction and arranged in a line in the second direction.

14. The integrated circuit of claim 11, wherein the front-side wiring layer further comprises a plurality of third patterns extending in the second direction and respectively spaced apart from the plurality of second patterns in the first direction, and
the plurality of through vias comprise a through via overlapping a contact between one of the plurality of first patterns and one of the plurality of third patterns in the vertical direction.

15. The integrated circuit of claim 10, further comprising a first wiring layer extending in a first direction between the dummy area and the front-side wiring layer,
wherein the plurality of through vias overlap the first wiring layer in the vertical direction and are arranged in a line in the first direction.

16. The integrated circuit of claim 10, further comprising a plurality of vias extending in the vertical direction over the substrate and connected between the plurality of through vias and the front-side wiring layer.

17. The integrated circuit of claim 10, further comprising a contact connected to a source/drain area of the at least one transistor,
wherein the back-side wiring layer is connected through the plurality of through vias, the front-side wiring layer, and the contact to the source/drain area of the at least one transistor.

18. The integrated circuit of claim 17, wherein a ground voltage applied to the back-side wiring layer passes through the plurality of through vias, the front-side wiring layer, and the contact to the source/drain area of the at least one transistor.

19. An integrated circuit comprising:
a substrate comprising a cell area and a dummy area adjacent to the cell area, wherein the cell area includes a plurality of cells;
a first wiring layer arranged over a front surface of the substrate in a vertical direction;
a second wiring layer arranged over the first wiring layer in the vertical direction and having a mesh shape across the cell area and the dummy area;
a back-side wiring layer which is arranged on a rear surface of the substrate and to which a first supply voltage is applied;
a through via overlapping the second wiring layer in the vertical direction in the dummy area and connected to the back-side wiring layer by passing through the substrate; and
a via extending in the vertical direction in the dummy area and connecting the through via to the first wiring layer,
wherein the first supply voltage is applied through the back-side wiring layer to pass through the through via, the via, the first wiring layer, and the second wiring layer to a source/drain area of at least one transistor included in the plurality of cells.

20. The integrated circuit of claim 19, further comprising a third wiring layer which is arranged over the second wiring layer in the vertical direction and to which a second supply voltage is applied,
and when the second supply voltage is applied to the third wiring layer, the second supply voltage passes through the second wiring layer, and the first wiring layer to the at least one transistor.
